(19) United States
(12) Patent Application Publication
(10) Pub. No.: US 2004/0259323 A1
(43) Pub. Date: Dec. 23, 2004

(54) Semiconductor structure containing field oxide and method for fabricating the same

(76) Inventor: Wei-Kang King, Ping-Chen City (TW)

Correspondence Address: BIRCH STEWART KOLASCH & BIRCH, PO BOX 747, FALLS CHURCH, VA, 22040-0747, US

(21) Appl. No.: 10/024,274

(22) Filed: Dec. 17, 2001

Related U.S. Application Data
(63) Continuation-in-part of application No. 09/568,933, filed on May 11, 2000, now abandoned.

(30) Foreign Application Priority Data
May 11, 1999 (TW) 88107600

(51) Int. Cl. H01L 21/76; H01L 29/00

(52) U.S. Cl. 438/439; 257/509

(57) ABSTRACT

A semiconductor structure containing a field oxide and a process for fabricating the semiconductor structure. The semiconductor structure includes a semiconductor substrate including an isolation region and an active region; a field oxide formed on the semiconductor substrate in the isolation region; a first pad layer formed on the semiconductor substrate in the active region; a second pad layer formed on the semiconductor substrate not covered by the first pad layer, wherein the second pad layer has a smaller thickness than the first pad layer; a mask layer formed on the first pad layer, wherein the mask layer has a larger width than the first pad layer to form a cavity beneath the mask layer and next to the first pad layer; and a mask filler filled in the cavity. By means of the local pad film thinning technique and by forming a mask filler to grow the field oxide layer, the bird's beak encroachment and the thinning effect of the field oxide layer can both be inhibited.

### CROSS REFERENCE TO RELATED APPLICATIONS

This application is a continuation-in-part of application Ser. No. 09/568,933 filed on May 11, 2000.

### BACKGROUND OF THE INVENTION

1. Field of the Invention

The present invention relates to a semiconductor structure containing a field oxide, and more particularly to a semiconductor structure containing a field oxide and a thin pad oxide layer, without a conventional nitride sidewall spacer or with only a very narrow nitride liner. This semiconductor structure can inhibit the bird's beak encroachment and the thinning effect of the field oxide layer.

2. Description of the Prior Art

Due to the improvement of the techniques for the production of integrated circuits in recent years, the number of semiconductor devices contained in a chip has increased, and the minimum dimensions of devices has become finer for higher integration. For example, the line width of a semiconductor device (i.e., a transistor) used prsently has entered the submicron level. However, despite decreased device dimensions, it is still required that the semiconductor devices in a chip be isolated from each other to obtain good properties. The main purpose of this device isolation technology is to form isolation region between devices. It is necessary to reduce the width of the isolation region as much as possible in order to free up more chip surface to accommodate a greater number of devices.

The local oxidation of silicon (LOCOS) process is a well-known device isolation technology, which involves forming a thick oxide layer as the insulating layer to effectively isolate the devices from each other. The process will be described below in more detail. Referring to FIG. 1A, a pad oxide layer 11 and a silicon nitride layer 12 are successively formed on a semiconductor substrate 10, such as a silicon wafer, as a mask layer 19. Then, the pad oxide layer 11 and silicon nitride layer 12 are patterned by photolithography and etching to form an opening 13, such that a portion of the semiconductor substrate 10 is exposed and the exposed region is called an isolation region 17.

Subsequently, referring to FIG. 1B, thermal oxidation is performed. For example, the silicon wafer 10 is placed in a furnace at a temperature of 800° C. to 1100° C. and oxygen gas is introduced. Thus, a thick field oxide layer 14 is formed to define an active region 18. Since the oxidation rate of the silicon nitride layer 12 is far lower than that of the silicon wafer 10, the silicon nitride layer 12 can serve as a mask during the thermal oxidation, such that the field oxide layer is formed on the exposed region. Finally, the pad oxide layer 11 and the silicon nitride layer 12 are removed. The device isolation process is thus completed.

The LOCOS process as mentioned above has simple procedures and good isolation effect; therefore, it has been a technically popular process. However, problems arise when device dimensions become finer, particularly in the submicron range. When a silicon wafer is subjected to thermal oxidation, the oxidation not only occurs on the exposed region but also on the unexposed region. In the vicinity of the opening 13, the oxygen is diffused through the pad oxide 11 so as to form a bird's beak structure 15. This is called bird's beak encroachment (BBE).

Many techniques such as NSLOCOS (nitride sidewall LOCOS) technique have been developed to solve BBE. For example, in U.S. Pat. No. 5,173,444, a sidewall spacer made of silicon nitride serves as a mask for forming a field oxide layer. Referring to FIG. 2A, first, a pad oxide layer 2 and a silicon nitride layer 3 are successively formed on a semiconductor substrate 1, such as a silicon wafer, to serve as mask layers. Then, the pad oxide layer 2 and silicon nitride layer 3 are patterned by photolithography and etching to form an opening 5. Thus, a portion of the semiconductor substrate 1 is exposed, and the exposed region is ready for forming the isolation layer. Then, the opening 5 is subjected to thermal oxidation to form a second silicon oxide layer 4, which is thinner than the pad oxide layer 2.

Subsequently, referring to FIG. 2B, a second silicon nitride layer 7 is formed by low pressure chemical vapor deposition (LPCVD) over the whole surface, and then anisotropically etched by reactive ion etching (RIE). Then, the second silicon oxide layer 4 thus exposed is removed by diluted hydrofluoric acid solution, leaving a residual silicon oxide layer 6 and a silicon nitride sidewall spacer 7a.

Subsequently, referring to FIG. 2C, a trench 8 is formed in the opening 5 of the silicon substrate 1 by self-aligning using the silicon nitride layer 3 and the silicon nitride sidewall spacer 7a as masks. Finally, a field oxide 9 is formed in the trench 8 by thermal oxidation as shown in FIG. 2D.

In the above-mentioned U.S. Patent, the silicon nitride sidewall spacer is used as a mask to block oxygen from invading the active region during thermal oxidation. Thus, BBE can be inhibited to an extent. However, when the design rule (device width) is smaller for higher integration, since the silicon nitride sidewall spacer occupies a relatively wide space, the field oxide can only be grown in a limited space. Thus, the field oxide has an insufficient depth, and the isolation effect is poor. This is called the thinning effect.

### SUMMARY OF THE INVENTION

The object of the present invention is to solve the above-mentioned problems and to provide a semiconductor structure containing a field oxide and a method for fabricating the semiconductor structure, which can inhibit the bird's beak encroachment and the thinning effect.

To achieve the above-mentioned object, according to a first aspect of the present invention, the semiconductor structure containing a field oxide includes a semiconductor substrate that includes an isolation region and an active region; a field oxide formed on the semiconductor substrate in the isolation region; a first pad layer formed on the semiconductor substrate in the active region; a second pad layer formed on the semiconductor substrate not covered by the first pad layer, wherein the second pad layer has a smaller thickness than the first pad layer; a mask layer formed on the first pad layer, wherein the mask layer has a larger width than the first pad layer to form a cavity beneath the mask layer and next to the first pad layer; and a mask filler in the cavity.

According to a second aspect of the present invention, the semiconductor structure containing a field oxide includes a semiconductor substrate that includes an isolation region and an active region; a field oxide formed on the semiconductor substrate in the isolation region; a first pad layer formed on the semiconductor substrate in the active region; a second pad layer formed on the semiconductor substrate not covered by the first pad layer, wherein the second pad layer has a smaller thickness than the first pad layer; a mask layer formed on the first pad layer, wherein the mask layer has a larger width than the first pad layer to form a cavity beneath the mask layer and next to the first pad layer; and a mask liner formed on the sidewall of the mask layer and filling cavity, wherein the mask liner has a width of 0 Å to 50 Å from the sidewall of the mask layer.

According to a third aspect of the present invention, the method for fabricating a field oxide includes (a) successively forming a first pad oxide layer and a first mask layer; (b) forming an opening in the first mask layer to define a region for forming the field oxide; (c) removing the first pad layer exposed by the opening to form a cavity; (d) forming a second pad layer having a smaller thickness than the first pad layer on the semiconductor substrate not covered by the first pad layer; (e) conformably forming a second mask layer on the semiconductor substrate and the first mask layer to fill the mask portion into the cavity; (f) isotropically etching the second mask layer to leave a mask filler in the cavity; and (g) carrying out thermal oxidation to form a field oxide in the opening.

According to a fourth aspect of the present invention, the method for fabricating a field oxide includes: (a) successively forming a first pad oxide layer and a first mask layer; (b) forming an opening in the first mask layer to define a region for forming the field oxide; (c) removing the first pad layer exposed by the opening to form a cavity; (d) forming a second pad layer having a smaller thickness than the first pad layer on the semiconductor substrate not covered by the first pad layer; (e) conformably forming a second mask layer on the semiconductor substrate and the first mask layer to fill the mask portion into the cavity; (f) isotropically etching the second mask layer to leave a mask liner on the sidewall of the first mask layer and in the cavity, wherein the mask liner has a width of 0 Å to 50 Å from the sidewall of the first mask layer; and (g) carrying out thermal oxidation to form a field oxide in the opening.

### BRIEF DESCRIPTION OF THE DRAWINGS

The present invention will become more fully understood from the detailed description given hereinbelow and the accompanying drawings, given by way of illustration only and thus not intended to be limitative of the present invention.

FIGS. 1A and 1B are cross-sections illustrating the process flow of forming the field oxide layer according to a conventional LOCOS.

FIGS. 2A-2D are cross-sections illustrating the process flow of forming the field oxide layer according to another conventional LOCOS, in which silicon nitride sidewalls are used as masks.

FIGS. 3A-3H are cross-sections illustrating the process flow of forming the field oxide layer according to a first preferred embodiment of the present invention.

FIGS. 4A-4B are cross-sections illustrating a portion of the process flow of forming the field oxide layer according to a second preferred embodiment of the present invention.

FIG. 5A is a SEM cross-sectional photograph of the semiconductor structure of the present invention before the field oxide layer is formed. This demonstrates that the mask liner 35 is very narrow.

FIG. 5B is a SEM cross-sectional photograph of the semiconductor structure (0.3 im 64 M DRAM) of the present invention after the field oxide layer is formed. This demonstrates that no BBE is found.

FIG. 5C is a photograph of a perspective view of the semiconductor structure of FIG. 5B. It can be seen that no BBE and no thinning effect are found, and the field oxide is adequately thick.

FIG. 5D is an electrical monitoring diagram showing the relationship between the voltage and leakage current. It can be seen that junction measurement result is good, showing that no silicon defect is induced by the isolation process.

FIG. 5E is a photograph of a perspective view of a conventional semiconductor structure without forming a second pad oxide 40 as in the present invention. It can be seen that there is severe silicon defect induced by high stress.

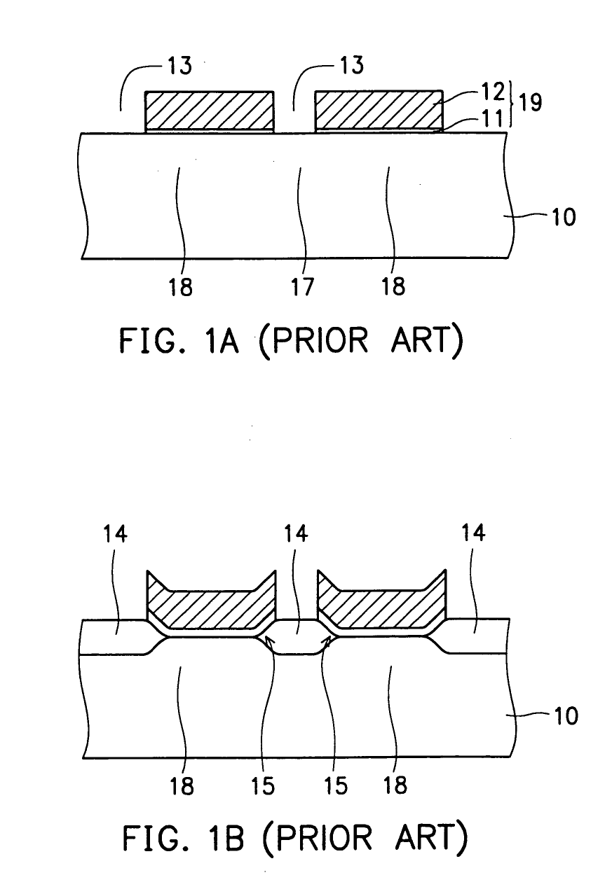

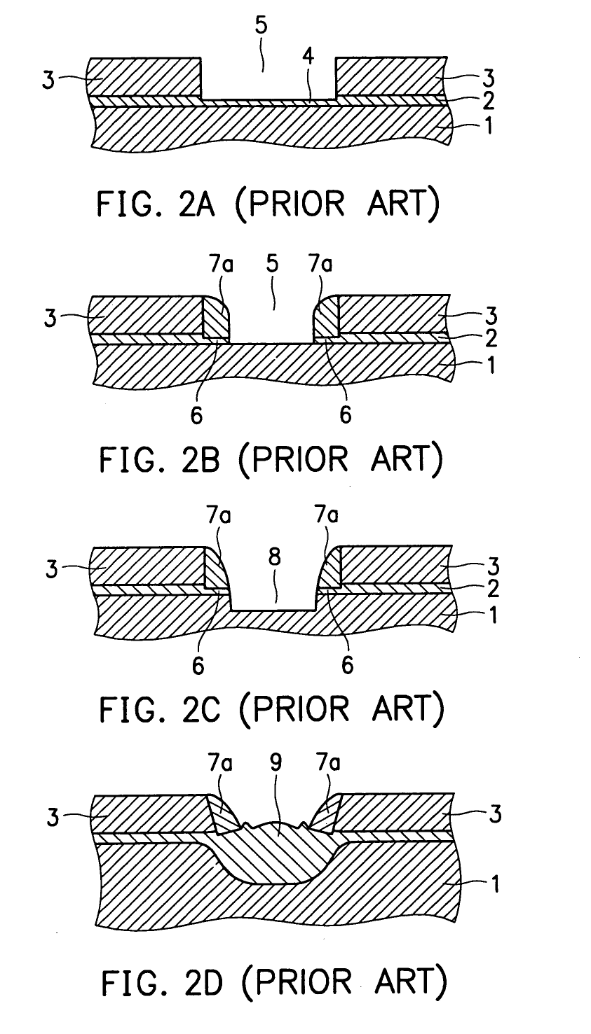

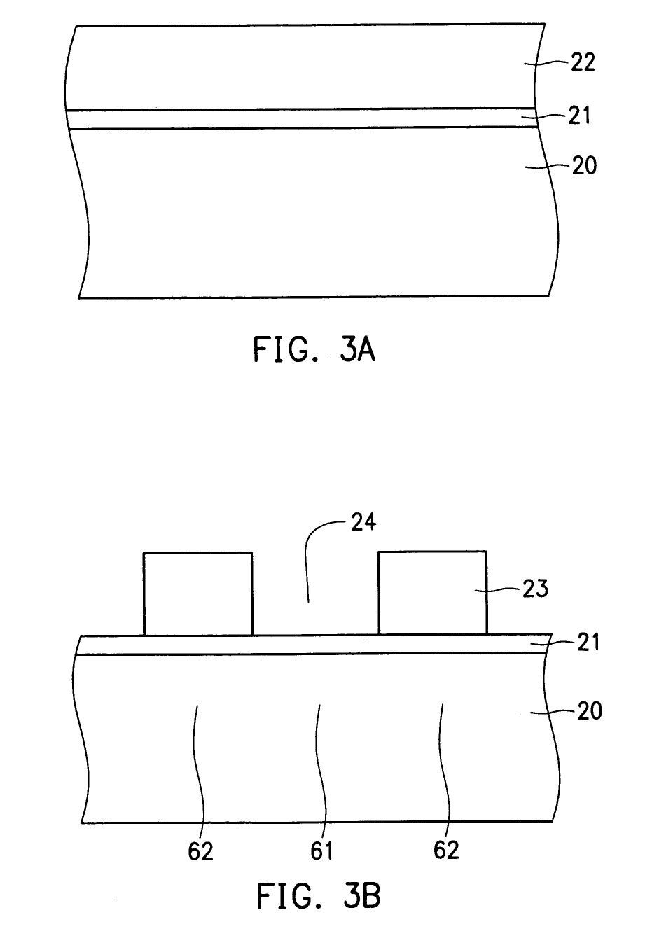

### DETAILED DESCRIPTION OF THE PREFERRED EMBODIMENTS

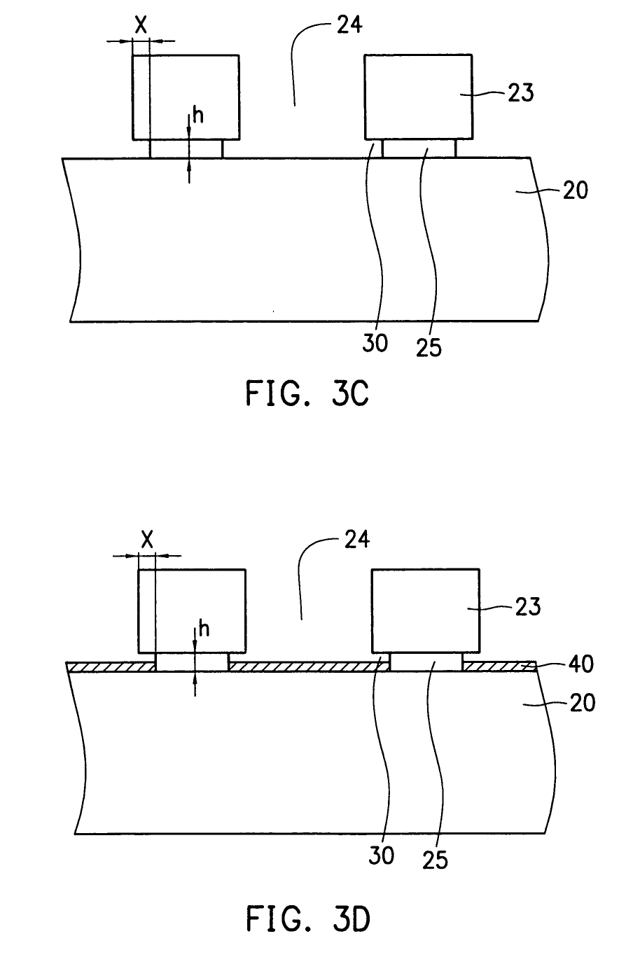

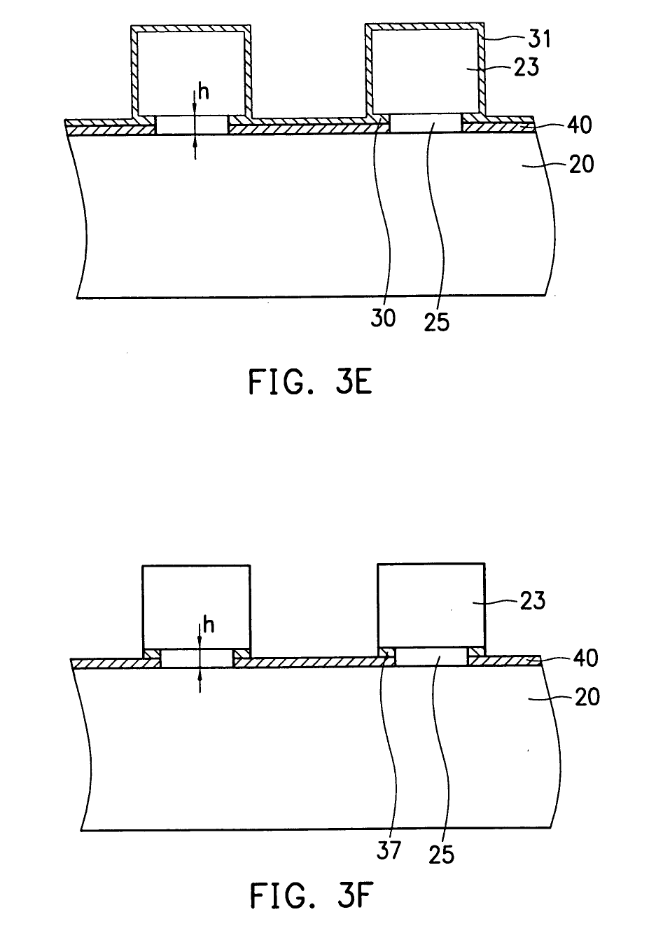

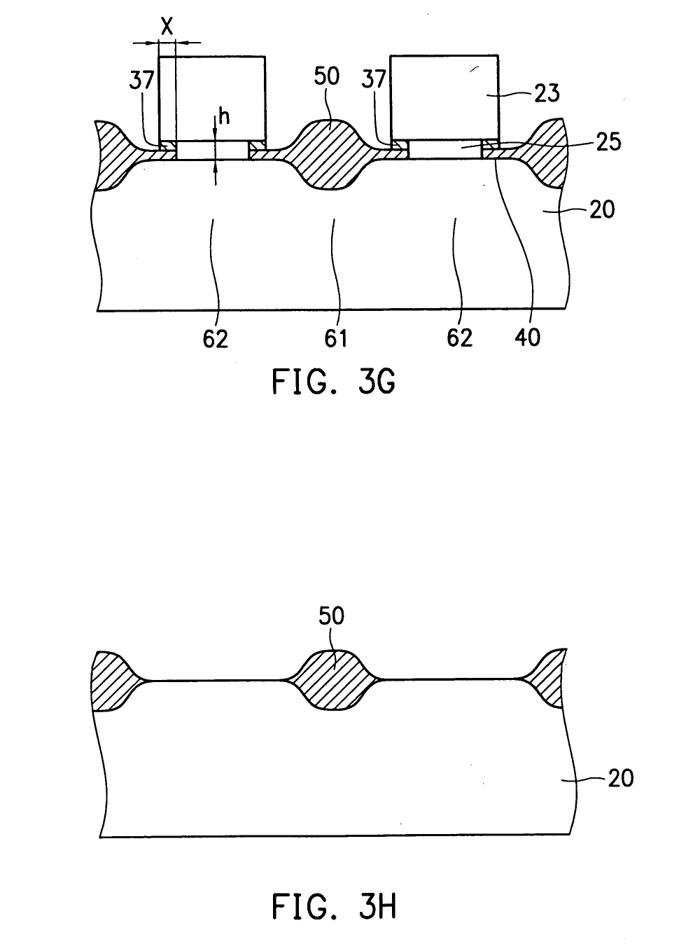

FIG. 3G shows a cross-section of a semiconductor structure containing a field oxide according to a first preferred embodiment of the present invention. In FIG. 3G, the semiconductor structure includes a semiconductor substrate 20, which includes an isolation region 61 and an active region 62. A field oxide 50 is formed on the semiconductor substrate 20 in the isolation region 61. A first pad layer 25 is formed on the semiconductor substrate 20 in the active region 62. A second pad layer 40 is formed on the semiconductor substrate 20 not covered by the first pad layer 25. The second pad layer 40 has a smaller thickness than the first pad layer 25. A mask layer 23 is formed on the first pad layer 25. The mask layer 23 has a larger width than the first pad layer 25 to form a cavity beneath the mask layer 23 and next to the first pad layer 25. The cavity is indented from the sidewall of the mask layer 23 by a width X. A mask filler 37 is filled in the cavity.

FIGS. 3A-3H are cross-sections illustrating the process flow of forming the semiconductor structure of FIG. 3G according to a first preferred embodiment of the present invention.

Referring to FIG. 3A, a first pad layer 21 and a first mask layer 22 are successively formed on a semiconductor substrate 20. The semiconductor substrate 20 can be made of silicon or germanium by means of a expitaxial or silicon on insulator method. P-type silicon substrate is taken as an example for better explanation. The first pad layer 21 can be a pad oxide layer, such as silicon oxide layer having a thickness h of 100 Å to 250 Å formed by means of thermal oxidation or chemical vapor deposition (CVD). The first mask layer 22 can be a silicon nitride layer having a thickness of 1500 Å to 2500 Å formed by means of the low pressure chemical vapor deposition (LPCVD) process using SiH₂Cl₂ and NH₃ as reactants.

Subsequently, referring to FIG. 3B, the first mask layer 22 is patterned by photolithography. For example, the first mask layer 22 is anisotropically etched by reactive ion etching (RIE) using a resist as a mask so as to form a patterned mask layer 23 and an opening 24. The region defined by the opening 24 is reserved to form a field oxide layer in the future, referred to as an isolation region 61. The region defined by the patterned mask layer 23 is reserved to form a semiconductor device in the future, referred to as an active region 62.

Subsequently, referring to FIG. 3C, the area of the first pad layer 21, exposed by the opening 24 is etched so as to form a cavity 30 beneath the patterned first mask layer 23. The cavity 30 is indented from the sidewall of the first mask layer 23 by a width X, for example, 300 Å to 700 Å, preferably 500 Å. The first pad layer 21 after etching is referred to as 25. The etching can be wet etching conducted by a hydrofluoric acid solution.

Subsequently, referring to FIG. 3D, a second pad layer 40 is formed on the semiconductor substrate 20 not covered by the first pad layer 25. The second pad layer 40 has a thickness less than the first pad layer 25; for example, it can be a silicon oxide layer having a thickness of 60 Å to 120 Å formed by thermal oxidation.

Subsequently, the step of filling a mask filler into the cavity 30 beneath the first mask layer 23 and next to the first pad layer 25 is performed. Referring to FIG. 3E, for example, a second mask layer 31 is conformably formed on the second pad layer 40 and the first mask layer 23 so as to fill the mask material into the cavity 30. Then, referring to FIG. 3F, the second mask layer 31 is isotropically etched until the second pad layer 40 in the isolation region 61 is exposed and no more second mask layer 31 remains on the sidewall of the first mask layer 23. Thus, in FIG. 3F, after isotropical etching, the original second mask layer 31 only remains in the cavity 30 beneath the first mask layer 23 and next to the first pad layer 25, which is referred to as a mask filler 37.

The second mask layer 31 can be a silicon nitride layer which is, for example, formed by means of LPCVD using SiH₂Cl₂ and NH₃ as reactants. The second mask layer 31 can be made as thin as possible, with the only requirement that the cavity 30 be fully filled with silicon nitride. Therefore, the thickness of the second mask (silicon nitride) layer 31 can be only 40 Å to 120 Å, which is far less than the thickness of a conventional nitride sidewall spacer. The silicon nitride layer 31 can be etched by means of isotropic RIE using plasma of a fluorine-containing gas as the main etching reactive gas. Suitable fluorine-containing gas can be nitrogen fluoride (NF₃), SF₆, and CF₄, preferably SF₆.

Subsequently, referring to FIG. 3G, thermal oxidation is conducted to form a field oxide layer on the isolation region 61. For example, the semiconductor substrate 20 is placed in a furnace at a temperature of 800° C. to 1150° C. and the oxygen gas is introduced for oxidation. Thus, a field oxide layer 50 having a thickness of 3500 Å to 5000 Å is formed on the isolation region 61 of the semiconductor substrate 20. Since the second pad layer (silicon oxide layer) 40 is very thin, when the field oxide layer grows, it is not easy for oxygen to diffuse horizontally along such a thin pad layer 40. Thus, in contrast to the conventional thicker pad layer, the bird's beak encroachment (BBE) in the active region can be greatly inhibited by means of the thinner pad layer of the present invention.

Generally speaking, the pad layer with inadequate thickness cannot take the stress generated when the field oxide grows, thus generating defects in the silicon substrate structure. The present invention uses the thinner second pad layer 40 to inhibit BBE; however, the high stress generated by the mask layer 23 can be solved by the thicker first pad layer 25 at the same time. Therefore, the stress can be effectively alleviated and the defects can be prevented.

As mentioned above, in the conventional process for solving BBE by means of silicon nitride sidewall spacers, since the silicon nitride spacer has occupied a relatively wide space, the field oxide layer can only grow in a limited portion of the opening. This worsens the thinning effect of the field oxide layer, and cannot meet the requirement for the present small design rule. In contrast, according to the first preferred embodiment of the present invention, the second mask layer 31 is isotropically etched until no more second mask layer 31 remains on the sidewall of the first mask layer 23, and the second mask layer 31 only remains in the cavity 30 beneath the first mask layer 23 and next to the first pad layer 25 as a mask filler 37. Therefore, there is no additional silicon nitride sidewall spacer occupying the space. The field oxide layer can be grown in a larger area of the opening. Thus, the thinning effect can be alleviated, and the field oxide layer with an adequate thickness can be grown at a smaller design rule, achieving a good isolation effect.

Finally, referring to FIG. 3H, the first mask layer 23, the first pad layer 25, the mask filler 37, and the second pad layer 40 are removed. For example, the first mask layer 23 and mask filler 37 can be removed by a heated phosphoric acid solution, and the first pad layer 25 and the second pad layer 40 can be removed by a diluted hydrofluoric acid solution. A structure as shown in FIG. 3H is thus obtained.

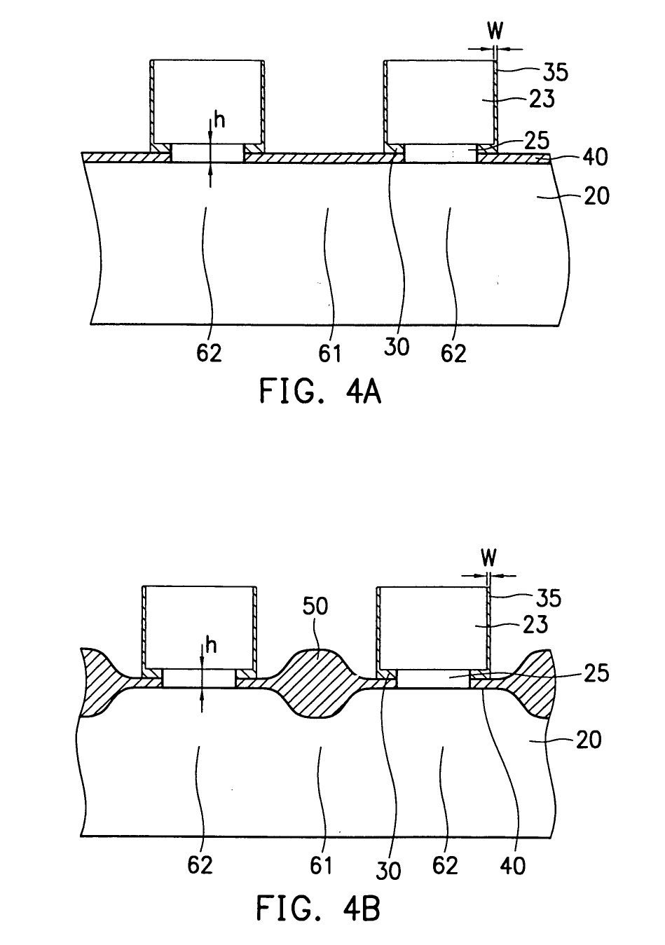

FIG. 4B shows a cross-section of a semiconductuctor structure containing a field oxide according to a second preferred embodiment of the present invention. The structure of FIG. 4B is almost the same as that of FIG. 3G, except that a mask filler 37 in FIG. 3G, filled in the cavity 30 beneath the first mask layer 23 and next to the first pad layer 25, is replaced by a mask liner 35. The mask liner 35 is formed on the sidewall of the first mask layer 23 and in the cavity 30. The mask liner 35 has a width W of 0 Å to 50 Å from the sidewall of the mask layer 23.

FIGS. 4A-4B are cross-sections illustrating a portion of the process flow of forming the semiconductor structure of FIG. 4B according to a second preferred embodiment of the present invention. The process flow from FIGS. 3A to 3E also applies to the second preferred embodiment of the present invention.

The process flow from FIGS. 3A to 3E is quickly described, and detailed and redundant descriptions are omitted here. Referring to FIG. 3A, a first pad layer 21 and a first mask layer 22 are successively formed on a semiconductor substrate 20.

Subsequently, referring to FIG. 3B, the first mask layer 22 is patterned by photolithography to form a first mask layer 23 and an opening 24. Subsequently, referring to FIG. 3C, the area of the first pad layer 21 exposed by the opening 24 is etched so as to form a cavity 30 beneath the patterned first mask layer 23, thus forming a first pad layer 25. Subsequently, referring to FIG. 3D, a second pad layer 40 having a thickness less than the first pad layer 25 is formed on the semiconductor substrate 20 not covered by the first pad layer 25. Subsequently, referring to FIG. 3E, a second mask layer 31 is conformably formed on the second pad layer 40 and the first mask layer 23 so as to fill the mask material into the cavity 30.

Subsequently, the step of forming a mask liner on the sidewall of the first mask layer 23 and in the cavity 30 is performed. Referring to FIG. 4A, the second mask layer 31 is isotropically etched until the second pad layer 40 in the isolation region 61 is exposed and only a very narrow second mask layer 31 remains on the sidewall of the first mask layer 23. Thus, in FIG. 4A, after isotropically etching, the original second mask layer 31 only remains both in the cavity 30 beneath the first mask layer 23 and next to the first pad layer 25 and on the sidewall of the first mask layer 23, which is referred to a mask liner 35. By means of isotropic etching, the width W of the mask liner 35 from the first mask layer 23 is made as narrow as possible, which is preferably 0 Å to 50 Å. As described above, the silicon nitride layer 31 can be etched by means of isotropic RIE using plasma of a fluorine-containing gas as the main etching reactive gas. Suitable fluorine-containing gas can be nitrogen fluoride (NF₃), SF₆, and CF₄, preferably SF₆.

Subsequently, referring to FIG. 4B, thermal oxidation is conducted to form a field oxide layer on the isolation region 61. As described above, since the second pad layer (silicon oxide layer) 40 is very thin, when the field oxide layer grows, it is not easy for oxygen to diffuse horizontally along such a thin pad layer 40. Thus, in contrast to the conventional thicker pad layer, the bird's beak encroachment (BBE) in the active region can be greatly inhibited by means of the thinner pad layer of the present invention. In addition,

Generally speaking, the pad layer with inadequate thickness cannot take the stress generated when the field oxide grows, thus generating defects in the silicon substrate structure. The present invention uses the thinner second pad layer 40 to inhibit BBE; however, the high stress generated by the mask layer 23 can be solved by the thicker first pad layer 25 at the same time. Therefore, the stress can be effectively alleviated and the defects can be prevented.

In the conventional process for solving BBE by means of silicon nitride sidewall spacers, since the silicon nitride spacer has occupied a relatively wide space, the field oxide layer can only grow in a limited portion of the opening. This worsens the thinning effect of the field oxide layer, and cannot meet the requirement for the present small design rule. In contrast, according to the second preferred embodiment of the present invention, a cavity 30 is formed beneath the first mask layer 23 and next to the first pad layer 25, and the second mask layer 31 can be made as thin as possible only if the cavity 30 is filled with the mask material. In addition, isotropically etching is conducted to remove the second mask layer 31 as much as possible. Therefore, the residual mask liner 35 can be made as narrow as possible to a width of 0 Å to 50 Å, which is much narrower than a conventional nitride sidewall spacer. Thus, the field oxide layer can be grown in a larger area of the opening. Thus, the thinning effect can be alleviated, and the field oxide layer with an adequate thickness can be grown at a smaller design rule, achieving a good isolation effect.

Finally, the first mask layer 23, the first pad layer 25, the mask liner 35, and the second pad layer 40 can be removed according to the description for FIG. 3H of the first preferred embodiment of the present invention. The final structure is shown in FIG. 3H.

In conclusion, by means of a thin pad oxide layer, it is not easy for oxygen to diffuse horizontally along such a thin pad oxide layer when the field oxide layer grows. Thus, in contrast to the conventional thicker pad layer, the bird's beak encroachment (BBE) in the active region can be greatly inhibited.

Moreover, the present invention uses a mask filler 37 or a very narrow mask liner 35 to keep oxygen from invading the active region during thermal oxidation. Therefore, the field oxide layer can be grown in a much wider space compared with a conventional process using a wider nitride sidewall spacer as a oxidation mask. Thus, the field oxide layer with sufficient thickness can be grown, and the thinning effect can be inhibited. The semiconductor structure is suitable for applying in 0.3 lm generation.

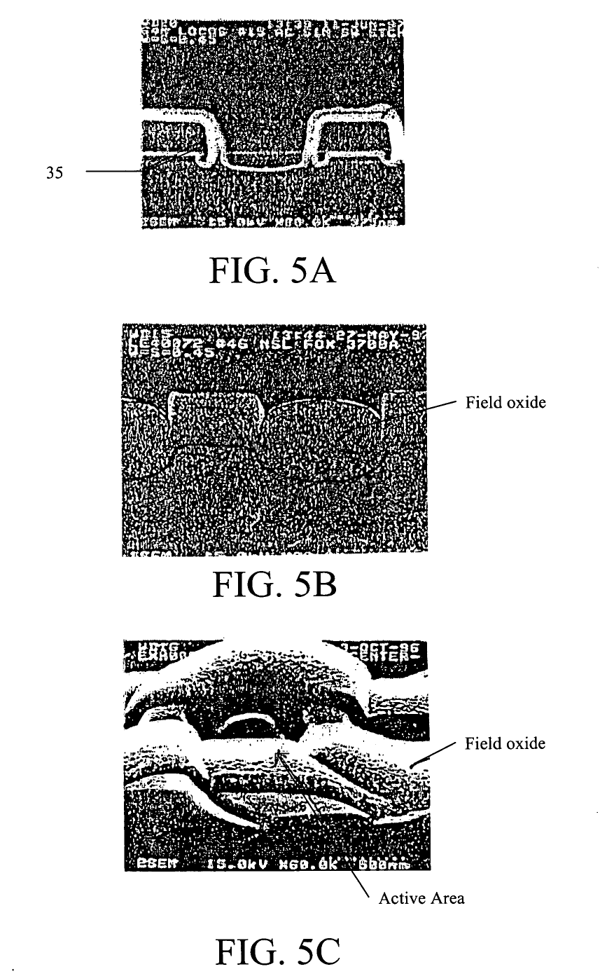

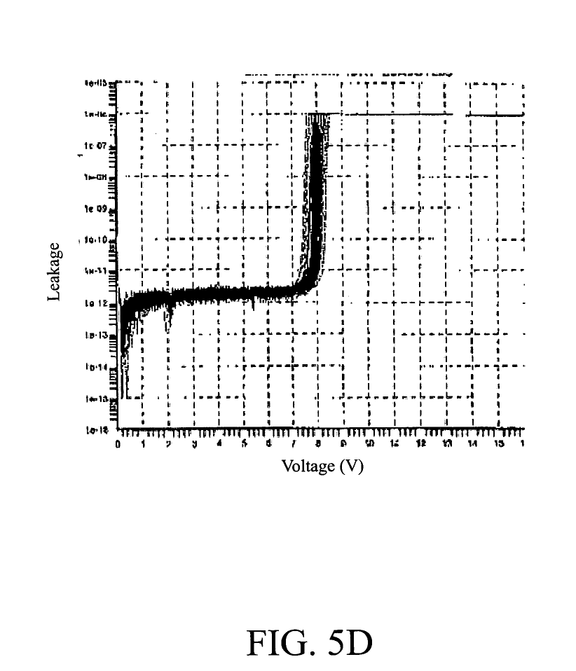

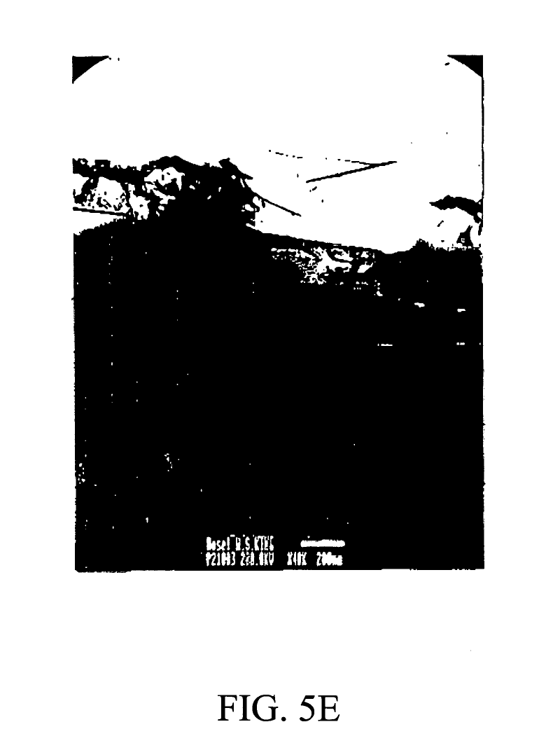

FIG. 5A is a SEM cross-sectional photograph of the semiconductor structure of the present invention before the field oxide layer is formed. This demonstrates that the mask liner 35 is very narrow. FIG. 5B is a SEM cross-sectional photograph of the semiconductor structure (0.3 im 64 M DRAM) of the present invention after the field oxide layer is formed. This demonstrates that no BBE is found. FIG. 5C is a photograph of a perspective view of the semiconductor structure of FIG. 5B. It can be seen that no BBE and no thinning effect are found, and the field oxide is adequately thick. FIG. 5D is an electrical monitoring diagram showing the relationship between the voltage and leakage current. It can be seen that junction measurement result is good, showing that no silicon defect is induced by the isolation process. FIG. 5E is a photograph of a perspective view of a conventional semiconductor structure without forming a second pad oxide 40 as in the present invention. It can be seen that there is severe silicon defect induced by high stress.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A semiconductor structure containing a field oxide, comprising:
a semiconductor substrate including an isolation region and an active region;
a field oxide formed on the semiconductor substrate in the isolation region;
a first pad layer formed on the semiconductor substrate in the active region;
a second pad layer formed on the semiconductor substrate not covered by the first pad layer, wherein the second pad layer has a smaller thickness than the first pad layer;
a mask layer formed on the first pad layer, wherein the mask layer has a larger width than the first pad layer to form a cavity beneath the mask layer and next to the first pad layer; and
a mask filler filled in the cavity.

2. The semiconductor structure as claimed in claim 1, wherein the first pad layer is an oxide.

3. The semiconductor structure as claimed in claim 1, wherein the second pad layer is an oxide.

4. The semiconductor structure as claimed in claim 1, wherein the first pad layer has a thickness of 100 Å to 250 Å.

5. The semiconductor structure as claimed in claim 1, wherein the second pad layer has a thickness of 60 Å to 120 Å.

6. The semiconductor structure as claimed in claim 1, wherein the mask layer is a nitride.

7. The semiconductor structure as claimed in claim 1, wherein the mask filler is a nitride.

8. The semiconductor structure as claimed in claim 1, wherein the cavity is indented from the sidewall of the mask layer by 300 Å to 700 Å.

9. A semiconductor structure containing a field oxide, comprising:
a semiconductor substrate including an isolation region and an active region;
a field oxide formed on the semiconductor substrate in the isolation region;
a first pad layer formed on the semiconductor substrate in the active region;
a second pad layer formed on the semiconductor substrate not covered by the first pad layer, wherein the second pad layer has a smaller thickness than the first pad layer;
a mask layer formed on the first pad layer, wherein the mask layer has a larger width than the first pad layer to form a cavity beneath the mask layer and next to the first pad layer; and
a mask liner formed on the sidewall of the mask layer and filled in the cavity, wherein the mask liner has a width of 0 Å to 50 Å from the sidewall of the mask layer.

10. The semiconductor structure as claimed in claim 9, wherein the mask liner is a nitride.

11. A method for fabricating a field oxide on a semiconductor substrate, comprising the steps of:
(a) successively forming a first pad oxide layer and a first mask layer;
(b) forming an opening in the first mask layer to define a region for forming the field oxide;
(c) removing the first pad layer exposed by the opening to form a cavity;
(d) forming a second pad layer having a smaller thickness than the first pad layer on the semiconductor substrate not covered by the first pad layer;
(e) conformably forming a second mask layer on the semiconductor substrate and the first mask layer to fill the mask portion into the cavity;
(f) isotropically etching the second mask layer to leave a mask filler in the cavity; and
(g) carrying out thermal oxidation to form the field oxide in the opening.

12. The method as claimed in claim 11, wherein step (c) is conducted by wet etching.

13. The method as claimed in claim 11, wherein step (d) is conducted by thermal oxidation.

14. The method as claimed in claim 11, wherein step (f) is conducted by isotropic RIE using plasma of a fluorine-containing gas as an etching reactive gas.

15. The method as claimed in claim 14, wherein step (f) is conducted by isotropic RIE using plasma of nitrogen fluoride (NF₃), SF₆, or CF₄ as an etching reactive gas.

16. The method as claimed in claim 15, wherein step (f) is conducted by isotropic RIE using plasma of SF₆ as an etching reactive gas.

17. A method for fabricating a field oxide on a semiconductor substrate, comprising the steps of:
(a) successively forming a first pad oxide layer and a first mask layer;
(b) forming an opening in the first mask layer to define a region for forming the field oxide;
(c) removing the first pad layer exposed by the opening to form a cavity;
(d) forming a second pad layer having a smaller thickness than the first pad layer on the semiconductor substrate not covered by the first pad layer;
(e) conformably forming a second mask layer on the semiconductor substrate and the first mask layer to fill the mask portion into the cavity;
(f) isotropically etching the second mask layer to leave a mask liner on the sidewall of the first mask layer and in the cavity, wherein the mask liner has a width of 0 Å to 50 Å from the sidewall of the first mask layer; and
(g) carrying out thermal oxidation to form the field oxide in the opening.
